(19) United States
(12) Patent Application Publication
(10) Pub. No.: US 2019/0066907 A1
(43) Pub. Date: Feb. 28, 2019

(54) Electronic Component and Process for Producing Same

(71) Applicant: Würth Elektronik GmbH & Co. KG, Niedernhall (DE)

(72) Inventors: Anatol Schwersenz, Neckarsulm (DE); Sebastian Schwiertz, Waldenburg (DE)

(73) Assignee: Würth Elektronik GmbH & Co. KG, Niedernhall (DE)

(21) Appl. No.: 16/081,359

(22) PCT Filed: Mar. 2, 2017
(86) PCT No.: PCT/EP2017/054872

§ 371 Date: Aug. 30, 2018

(30) Foreign Application Priority Data
Mar. 4, 2016 (DE) 10 2106 203 613.0

(51) Int. Cl. H01F 27/28; H05K 1/18; H01F 27/24; H02M 3/08; H01F 27/32; H01F 41/04; H01F 41/12

(52) U.S. Cl. CPC H01F 27/2804; H05K 1/183; H01F 27/24; H02M 3/08; H01F 27/32; H05K 3/4697; H01F 41/12; H01F 2027/2809; H05K 2201/1006; H05K 2201/1003; H01F 41/041

(57) ABSTRACT

The invention relates to an electronic component with a cavity in which a magnetic circuit is arranged, the magnetic circuit being formed by the first and second magnetic conductor elements, which have at least one planar coil located between them, each of the magnetic conductor elements having at least one bridge-shaped area, and the turns of the planar coils passing through between the bridge-shaped areas of the magnetic conductor elements, each of the bridge-shaped areas having a first end, the first ends that are opposite one another forming a coil core for the planar coil, and the bridge-shaped areas each having a second end, the opposite second ends closing the magnetic circuit on the periphery of the planar coil.

### CROSS-REFERENCE TO RELATED APPLICATION(S)

This application is a national stage application of and claims priority to International Patent Application No. PCT/EP2017/054872 entitled “Electronic Component and Method for the Production Thereof” filed on Mar. 2, 2017, which claims priority to German Patent Application No. DE102016203613.0 entitled “Elektronisches Bauelement and Verfahren zu dessen Herstellung” filed on Mar. 4, 2016, both of which are incorporated herein by reference.

### FIELD

The invention relates to an electronic component for realizing an inductance, in particular of a transformer, and a production process for an electronic component.

### BACKGROUND

The prior art discloses planar coils in which the coil turns are put onto the surface of a substrate. Such known planar coils can achieve only a relatively small inductance in a cost-effective way, and the planar coils also occupy a relatively large amount of space on the substrate surface.

DE 10 2012 216101 discloses a process for producing a coil that is integrated into a substrate or put on a substrate, this process involving turn sections of the coil passing through the core material of the coil.

US 2012/0011709 A1 discloses a discrete electronic component with an inductance, this component having a cylindrical coil core.

The publication US 2009/0237899 A1 discloses a magnetic component that is arranged in a printed circuit board. To accomplish this, the printed circuit board has a recess in which an E-shaped core element can be put. This E-shaped core element can have a coil put in it, and a rod-shaped element can be provided on the top of the E-shaped core element.

### SUMMARY

By contrast, the invention has the goal of creating an improved electronic component and a process for producing it.

Each of the goals of the invention is achieved by the features of the independent claims. Embodiments of the invention are specified in the dependent claims.

According to embodiments of the invention, the electronic component has a cavity, in which a magnetic circuit is arranged. The magnetic circuit is formed by at least one planar coil, which is located between first and second magnetic conductor elements. Each of the magnetic conductor elements has a first end, the first ends being arranged opposite one another and extending in the axial direction of the planar coil. The first ends of the magnetic conductor elements, these first ends lying opposite one another, form a coil core for the planar coil.

The second ends of the magnetic conductor elements are arranged on the periphery of the planar coil and lie opposite one another there. Each of the magnetic conductor elements has at least one bridge-shaped area that connects together the first and second ends of the magnetic conductor element in question, closing the magnetic circuit. Each of the bridge-shaped areas of the magnetic conductor elements can extend parallel to the plane of the planar coil between its center and its periphery, so that the turns of the planar coil pass through between the first and second ends and the bridge-shaped areas lying opposite one another of the two conductor elements that are arranged opposite one another.

Embodiments of the invention are especially advantageous since the electronic component can achieve a relatively large inductance while having a relatively small mass. Furthermore, [use of] the planar coil allows the electronic component to have a small overall height, so that if the electronic component is arranged on a printed circuit board, for example, only a small moment of tilt results, even at high accelerations. Therefore, embodiments of the electronic component are especially suitable for means of transport such as, for example automobiles, airplanes, and ships, in which high mechanical stresses can occur, and/or for applications, in which reliability is especially important, such as, for example medical technology devices, especially implants.

Embodiments of the invention are also especially advantageous, since it is possible to realize a relatively large inductance with a relatively small ohmic resistance, and thus the reactive power and waste heat are correspondingly small. The electronic component can have, for example, a power consumption between 10 watts and 100 watts, in particular 50 watts.

According to embodiments of the invention, each of the first and second magnetic conductor elements has multiple bridge-shaped areas, each of which is arranged around the first ends, for example in the shape of a star, especially in the shape of an x. The individual bridge-shaped areas of one of the magnetic conductor elements can be arranged around the first end of the magnetic conductor element in question, at the same or different angular distances.

According to embodiments of the invention, the at least one planar coil is put on a printed circuit board layer. The planar coil is produced, for example, in a separate manufacturing process, for example a lithographic process, in order then to use the planar coil to produce the electronic component.

According to one embodiment of the invention, the electronic component comprises a first planar coil to form the primary side of a transformer, and a second planar coil to form the secondary side of a transformer. The first and second planar coils are arranged between the first and second magnetic conductor elements, the first ends forming the coil core, i.e., here the transformer core of the transformer.

For example, the planar coils can be designed to be mirror symmetric with respect to one another by producing them with identical lithographic processes. This has the advantage that it makes it possible to achieve a small manufacturing tolerance of the electronic component.

According to one embodiment of the invention, the first and/or second planar coils, for example, are formed by the planar coil in question having a first part of its turns on a first side of its printed circuit board layer and a second part of the turns of the planar coil being arranged on the second side of the printed circuit board layer opposite the first side. The first and second parts are connected by a via through the printed circuit board layer, resulting in a planar coil that has the turn sections on the two opposite sides of the plane formed by the printed circuit board layer. This has the advantage that it can further increase the inductance at low cost, using little material, and with small overall height.

According to embodiments of the invention, a coil package, for example with one planar coil or with first and second planar coils, is created as a structural unit by providing other printed circuit board layers as insulating layers for the coil turns. Such a structural unit can be produced in a separate process, in order then to use the structural unit to produce the electronic component, by putting the structural unit between the first and second magnetic conductor elements.

According to one embodiment of the invention, the first and second magnetic conductor elements are designed so that the end faces of the respective opposite second ends touch one another, creating especially good mechanical stability. In particular, tilting of the magnetic conductor elements relative to one another is avoided, even under large mechanical loads, since the second ends of the magnetic conductor elements rest on one another.

According to one embodiment of the invention, there is an air gap between the first ends of the conductor elements in the center of the at least one planar coil. Such an air gap can be advantageous, to avoid an operating point in the magnetic saturation. In particular, the air gap allows the electronic component to operate in the approximately linear range of the hysteresis loop of the magnetic circuit. On the other hand, the air gap between the first ends is also mechanically advantageous, since it avoids a double fit requirement with respect to the second ends, and produces a defined mechanical contact at the opposite second ends.

According to one embodiment of the invention, the cavity in which the magnetic circuit is arranged is formed by one or more printed circuit board layers of the electronic component, the printed circuit board layers having a coefficient of thermal expansion that is greater than that of the ferrite of which the magnetic conductor elements consist. Then, if the temperature increases, the cavity expands more than the magnetic circuit does, so that a gap can form between the magnetic circuit and the cavity. In order to fix the magnetic circuit securely within the cavity even if the temperature increases, an elastic element can be arranged in the cavity to avoid the formation of such a gap due to a temperature increase. The elastic element can be a spring element and/or a foam, for example polyurethane.

According to one embodiment of the invention, one or more of the spring elements is/are formed in a printed circuit board layer, for example by pressing in and/or laser processing. Such a printed circuit board layer with spring elements can be integrated in the electronic component, each of the spring element(s) being located in one of the cavities, in order to compensate for the tolerances there due to a temperature increase.

According to one embodiment of the invention, the sum of the end faces of the second ends of the magnetic conductor elements is equal to the sum of the end faces of the first ends. That is, if each of the magnetic conductor elements has only one second end, the end faces of the second ends are the same size as the end faces of the first ends, so that the cross section of the magnetic circuit is approximately equal at each of the first and second ends.

By contrast, if each of the magnetic conductor elements has multiple second ends, such as, for example two, three, or four second ends in an x-shaped formation, then in the latter case every end face of the second ends has approximately a quarter of the end surface of the second end, so that even in this case the magnetic circuit once again also has an approximately equal effective cross section at the first ends and the second ends, which is advantageous for conducting the magnetic flux.

Another aspect of the invention relates to a printed circuit board, which can have a single-layer or multilayer design, with an inventive electronic component that can be arranged on or in the printed circuit board. In particular, the electronic component can be in the form of a discrete electronic component. The electronic component can have, for example, connection contacts produced using the SMD technique, these connection contacts producing electrical contacts with a circuit of the printed circuit board and fixing the electronic component on the printed circuit board.

According to one embodiment of the invention, the electronic component is in the form of a transformer and serves to make available an operating voltage for a circuit of the printed circuit board. The circuit of the printed circuit board can serve, for example, to drive a light-emitting diode, such as, for example for the light-emitting diode of an automobile headlight.

Another aspect of the invention relates to a production process for an electronic component. First, a coil package consisting of one or more planar coils is produced. The coil package is put between the first and second magnetic conductor elements and put into a cavity of a single-layer or multilayer printed circuit board.

According to one embodiment of the invention, the individual components of the electronic component are first arranged in a stack structure, which is formed into a structural unit in a so-called multilayer process by applying pressure at a high temperature.

### BRIEF DESCRIPTION OF THE DRAWINGS

Embodiments of the invention will be explained in detail below with reference to the figures. The figures are as follows:

FIG. 1 a cross section through a stack structure of a first embodiment of an inventive electronic component;

FIG. 2 depicts an embodiment of the primary and secondary coils;

FIGS. 3a-3d depict an embodiment of the production of the primary and secondary coils;

FIGS. 4a-4d depict an embodiment of the first and second magnetic conductor elements;

FIG. 5 depicts an embodiment of an electronic component with a spring mechanism;

FIG. 6 depicts an embodiment of a stack structure of the electronic component with a spring mechanism;

FIG. 7 depicts the stack structure of FIG. 6 after a multilayer process is carried out;

FIG. 8 depicts an embodiment of an electronic component with a foam;

FIG. 9 depicts another embodiment of an electronic component with a foam;

FIG. 10 depicts an embodiment of a printed circuit board with an embodiment of a discrete electronic component arranged on it;

FIG. 11 depicts an embodiment of a LAN transformer with common mode choke; and

FIG. 12 depicts an embodiment of a SEPIC converter.

In the following description of the embodiments, elements that correspond to one another or are the same are always labeled with identical reference numbers.

### DETAILED DESCRIPTION OF ILLUSTRATIVE EMBODIMENTS

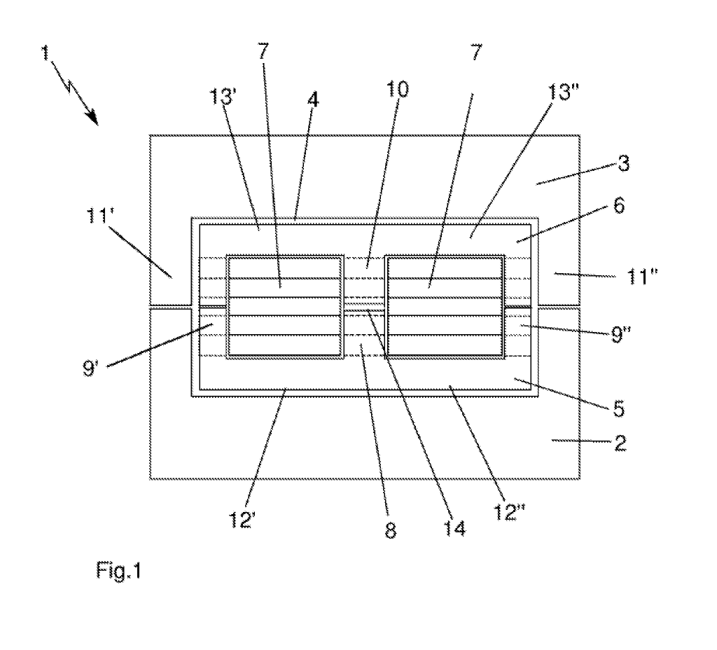

FIG. 1 shows a cross-sectional view of an embodiment of an inventive discrete electronic component 1. The component 1 has, for example, a lower printed circuit board layer 2 and an upper printed circuit board layer 3, which are shaped so that a cavity 4 results between the printed circuit board layers 2 and 3. The cavity can be milled or, if produced in larger numbers, it can be put into both printed circuit board layers, or at least into one printed circuit board layer, with a corresponding forming tool, e.g., it can be embossed, e.g., by means of an embossing roller.

Each of the printed circuit board layers can be a so-called prepreg. In particular, it can be a glass fiber mat soaked with epoxy resin (for example, FR-4 materials).

The cavity 4 has a magnetic circuit arranged in it, which is formed by a first magnetic conductor element 5, a second magnetic conductor element 6, and a coil package 7 arranged between the conductor elements 5 and 6, this coil package 7 having at least one planar coil. The magnetic conductor element 5 has a first end 8, which projects in the axial direction into a central opening of the coil package 7. The magnetic conductor element 5 also has two second ends 9′ and 9″ on the periphery of the coil package 7.

The magnetic conductor element 6 has a corresponding first end 10, which is opposite the first end 8 in the central opening of the coil package 7, and second ends 11′ and 11″, which are opposite the second ends 9′ and 9″. For example, the magnetic conductor elements 5 and 6 are identical, so that if the component 1 is mass produced, the same components can be used to realize the conductor elements 5 and 6.

The conductor elements 5, 6 can be bow-shaped, for example. In the embodiment of FIG. 1, each of the conductor elements 5, 6 has two bridge-shaped areas, i.e., the conductor element 5 has the bridge-shaped areas 12′ and 12″, which connect the first end 8 with each of the second ends 9′ and 9″ and the magnetic conductor element 6 has the bridge-shaped areas 13′ and 13″, each of which connects the first end 10 with the second ends 11′ and 11″.

Each of the magnetic conductor elements 5, 6 consists of a ferrite having a high magnetic permeability.

In the representation according to FIG. 1, the turns of the planar coil of the coil package 10 run in a circle around the first ends 8 and 10, perpendicular to the plane of projection. The first ends 8, 10 form the coil core. The magnetic circuit is closed by the bridge-shaped areas that span the coil package 7, on one side by the second ends 9′ and 11′ that are opposite one another and, on the other side, by the ends 9″ and 11″ that are opposite one another.

FIG. 1 shows component 1 in a stack structure, in which the printed circuit board layers 2 and 3 are connected together into a structural unit, which can be done by a printed circuit board process known in the art. For example, this can be accomplished by pressing the printed circuit board layers 2 and 3 onto one another at an elevated temperature.

According to embodiments of the invention, the end faces of the second ends 9′ and 11′ or 9″ and 10″ lie on top of one another, while an air gap 14 remains between the end faces of the first ends 8 and 10.

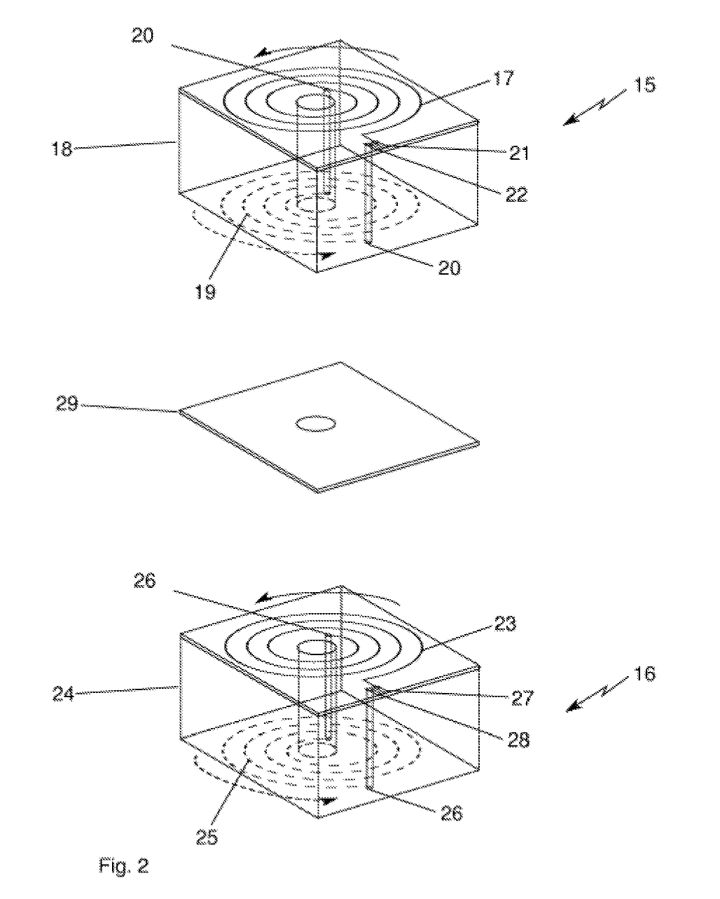

FIG. 2 shows an embodiment of the invention for producing the coil package 7 with a primary coil 15 and a secondary coil 16.

The procedure to produce the primary coil 15 involves first applying a first part 17 of the turns of the primary coil 15, for example on the top of a printed circuit board layer 18, for example using a lithographic process, and, by contrast, applying a second part 19 of the turns of the primary coil 15 on the bottom of the printed circuit board layer 18. The parts 17 and 19 of the primary coil 15 are electrically connected with one another by a feedthrough 20, that is, a so-called via through the printed circuit board layer 18. The resulting primary coil 15 has connection contacts 21 and 22.

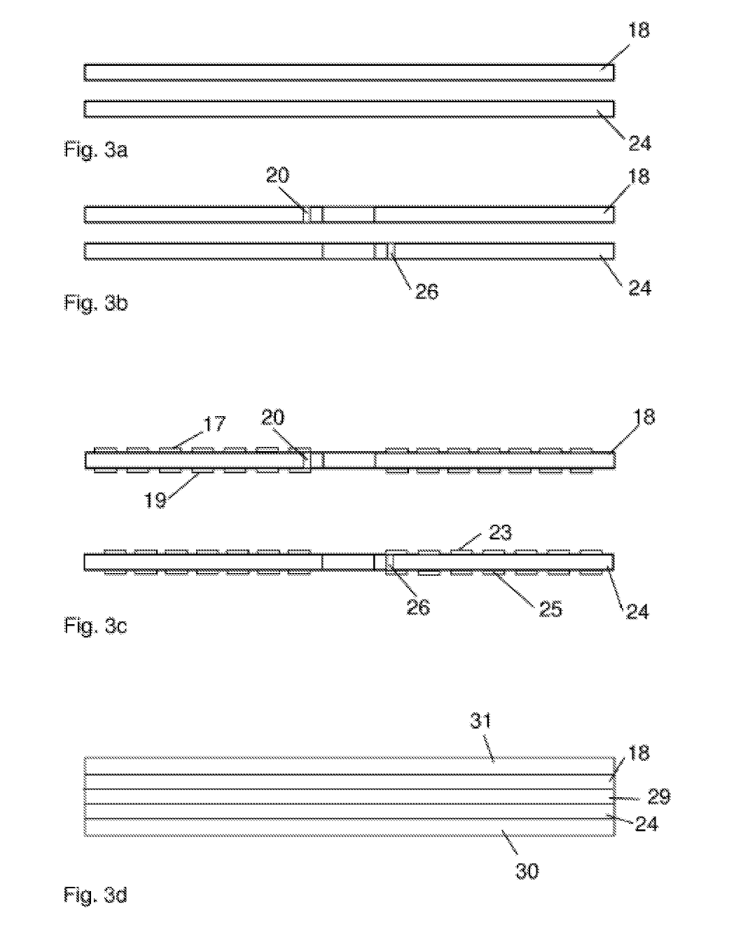

The procedure to produce the secondary coil 16 is analogous, and involves applying a part 23 of the turns of the secondary coil 16, for example on the top of a printed circuit board layer 24, and applying a second part 25 of the secondary coil 16 on the bottom of the printed circuit board layer 24, the parts 23 and 25 being electrically connected with one another by a feedthrough 26 (cf. FIG. 3b). The resulting secondary coil 16 has connection contacts 27 and 28.

FIG. 3 shows the corresponding process steps. In the first step (FIG. 3a), the printed circuit board layers 18 and 24 are made available. In the second step (FIG. 3b) the printed circuit board layers 18 and 24 have the feedthroughs 20 and 26 put in them, which can be done using processes known in the art for producing so-called vias. According to one embodiment of the invention, first the feedthroughs 20 and 26 are produced and then the conductor tracks are created.

In the third step (FIG. 3c) the primary coil 15 and the secondary coil 16 are produced by applying the parts 17 and 19 or 22 and 23, respectively, on the top or bottom of the respective printed circuit board layers 18 and 24. That is, the primary coil 15 is produced by first providing the printed circuit board layer 18 with the feedthrough 20, and then applying the conductor track of part 17 of the turns of the primary coil 15 onto the top of the printed circuit board layer 18 and part 19 of the turns of the primary coil 15 onto the bottom of the printed circuit board layer 18, the parts 17 and 19 of the turns being connected with one another through the feedthrough 20. An analogous procedure is used to produce the secondary coil 16 with the parts 23 and 25 of the turn of the secondary coil 16, by applying part 23 onto the top of the printed circuit board layer 24 and part 25 onto the bottom of the printed circuit board layer 24, after the feedthrough 26 has been produced.

In the fourth step, the coil package 7 is then formed (FIG. 3d), by putting another layer 29 between the printed circuit board layers 18 and 24, another layer 30 under the printed circuit board layer 24, and another layer 31 onto the printed circuit board layer 18, the other layers 29, 30, and 31 acting as electrical insulators. A printed circuit board process known in the art creates, from the layers 30, 24, 29, 18, and 31, a multilayer printed circuit board (MLPCB) as a structural unit to realize the coil package 7.

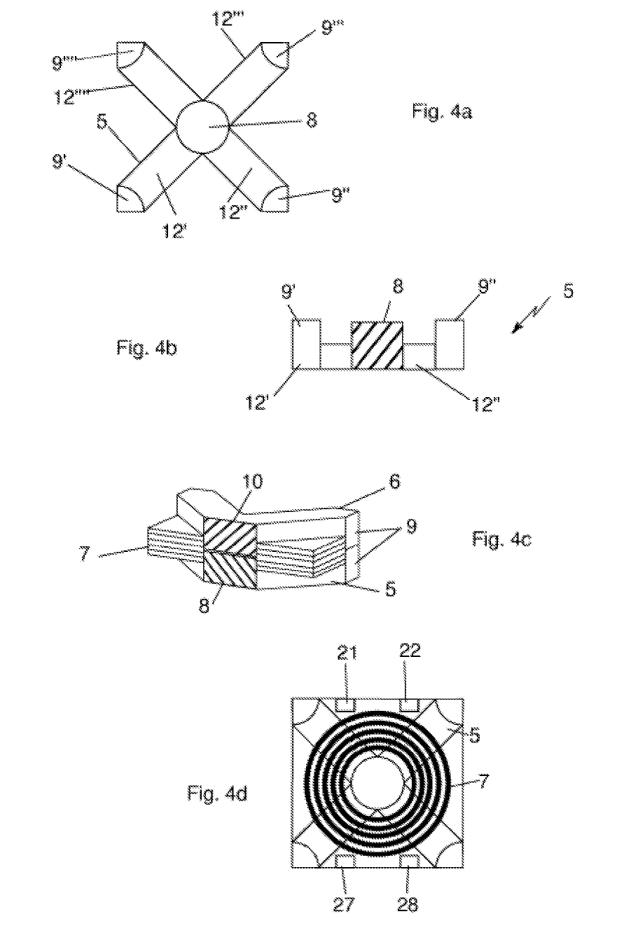

FIG. 4a is a top view of another embodiment of a magnetic conductor element 5, which here is X-shaped with four bridge-shaped areas 12. Here each of the individual bridge-shaped areas includes a right angle with other bridge-shaped areas. Embodiments are also possible in which the bridge-shaped areas include the same or different angles with other bridge-shaped areas. Likewise, the number of bridge-shaped areas that an individual conductor element 5, 6 has can vary, and can be, e.g., 2, 3, 4, 5, or 6. Both conductor elements 5, 6 have an identical number of the number of bridge-shaped areas.

In the embodiment according to FIG. 4a, the sum of the end faces of the second ends 9, i.e., 9′, 9″, 9′, and 9″, is the same as the end face of the first end 8, which is advantageous for conducting the magnetic flux, which is not narrowed by the effective cross section.

FIG. 4b shows a lateral section of the magnetic conductor element 5 of FIG. 4a.

FIG. 4c is a perspective view showing the magnetic conductor elements 5 and 6, which are identical to one another in the embodiment seen here.

FIG. 4d is a top view of the resulting finished construction of the magnetic circuit with the conductor elements 5 (at the top, not shown) and 6 arranged on top of one another and the coil package 7 located between them.

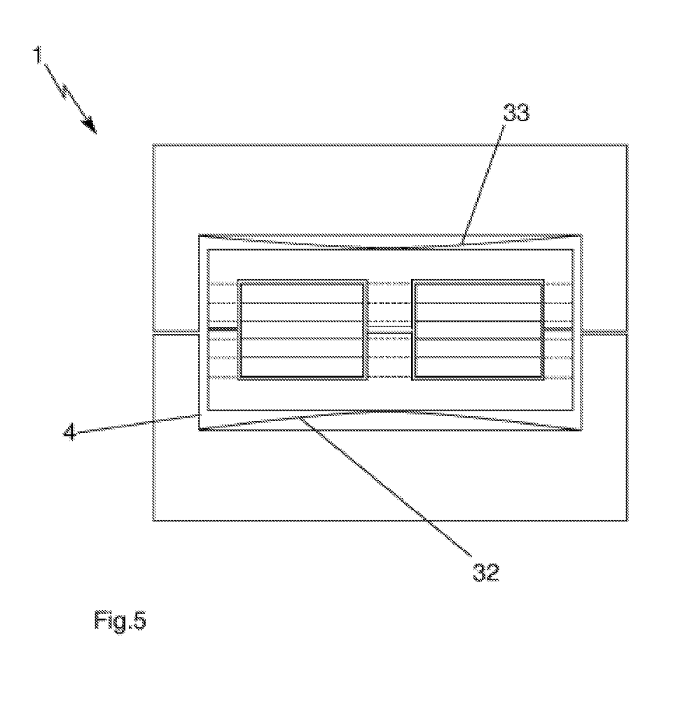

FIG. 5 shows an embodiment of the component 1 with spring elements 32, 33, which are arranged in the cavity 4, to press the magnetic conductor elements 5 and 6 against one another. This ensures that even if there are changes in temperature accompanied by changes in the length of the cavity 4 and the ferrite cores, the magnetic conductor elements 5 and 6 remain in mechanical contact with one another, so that the magnetic circuit remains intact.

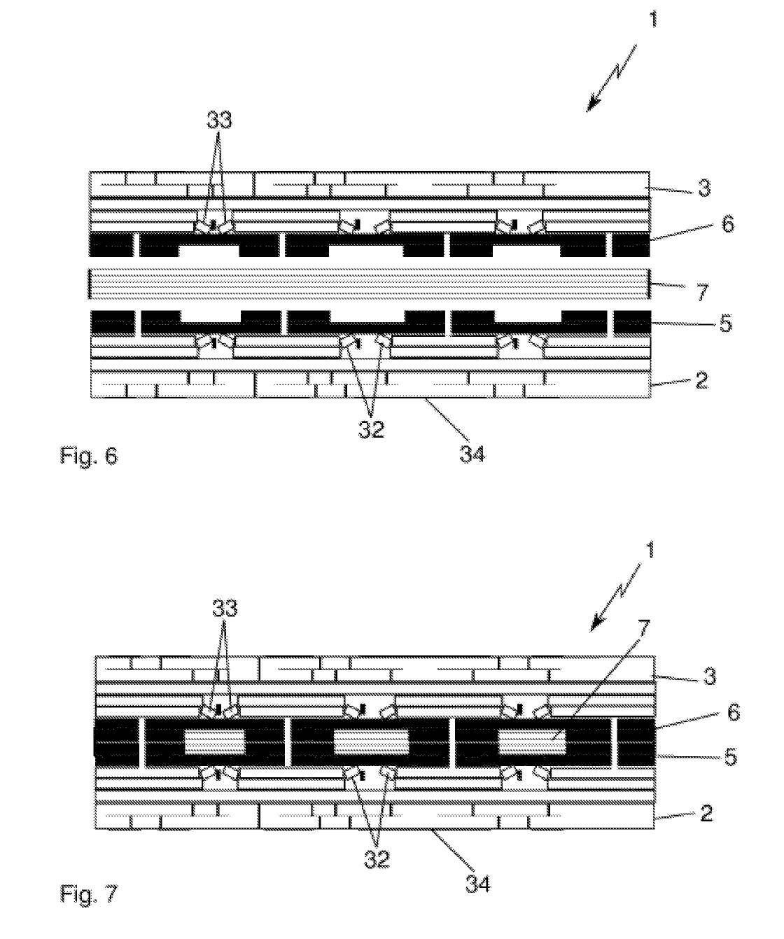

FIG. 6 shows a detail of an embodiment of component 1, which has a coil package 7 with three pairs of primary and secondary coils in it. Spring elements 32 and 33 can be formed in a layer of material, e.g., a glass fiber mat or a prepreg material, this layer being part of the layer structure of component 1. Spring elements 32 and 33 are designed to press the magnetic conductor elements 5 and 6 against one another after the multilayer process is carried out, as is shown in FIG. 7, in particular to do so even if there are changes in temperature accompanied by changes in the length of the cavity 4 and the ferrite cores.

FIG. 6 shows component 1 as a stack structure before the multilayer process is carried out; FIG. 7 shows the component 1 in the finished state, after the multilayer process has been carried out, creating a structural unit of the component 1.

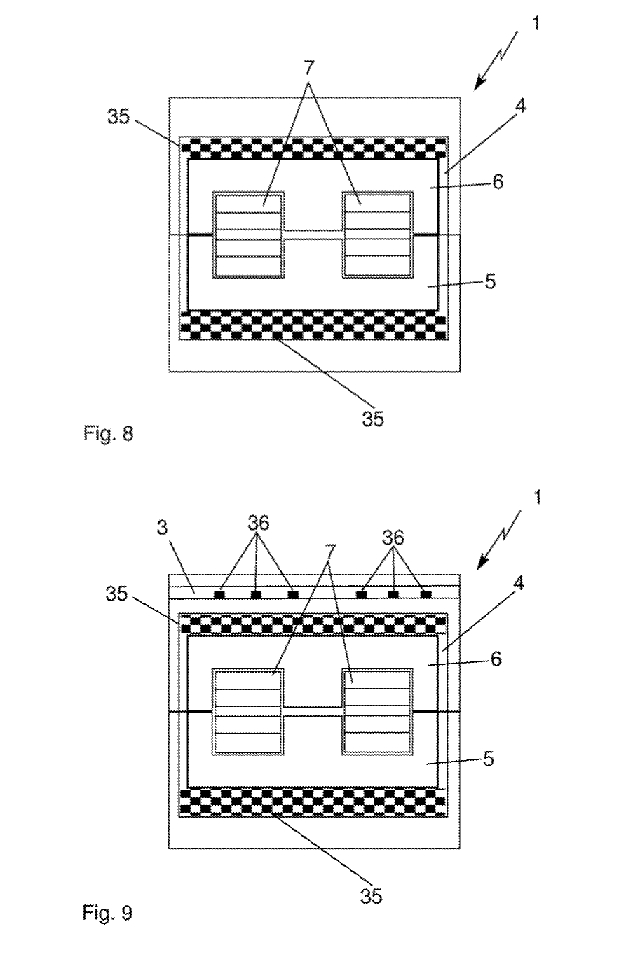

FIG. 8 shows an embodiment that is an alternative to that of FIG. 5; in this alternative embodiment the spring elements 32, 33 have been replaced by a foam filling at the top and bottom of cavity 4. For example, polyurethane foam 35 is used for this purpose.

FIG. 9 shows a further development of the embodiment according to FIG. 8, the embodiment according to FIG. 9 having electronic components 36 arranged on or in the printed circuit board layer 3. These electronic components 36 can be connected with the coil package 7.

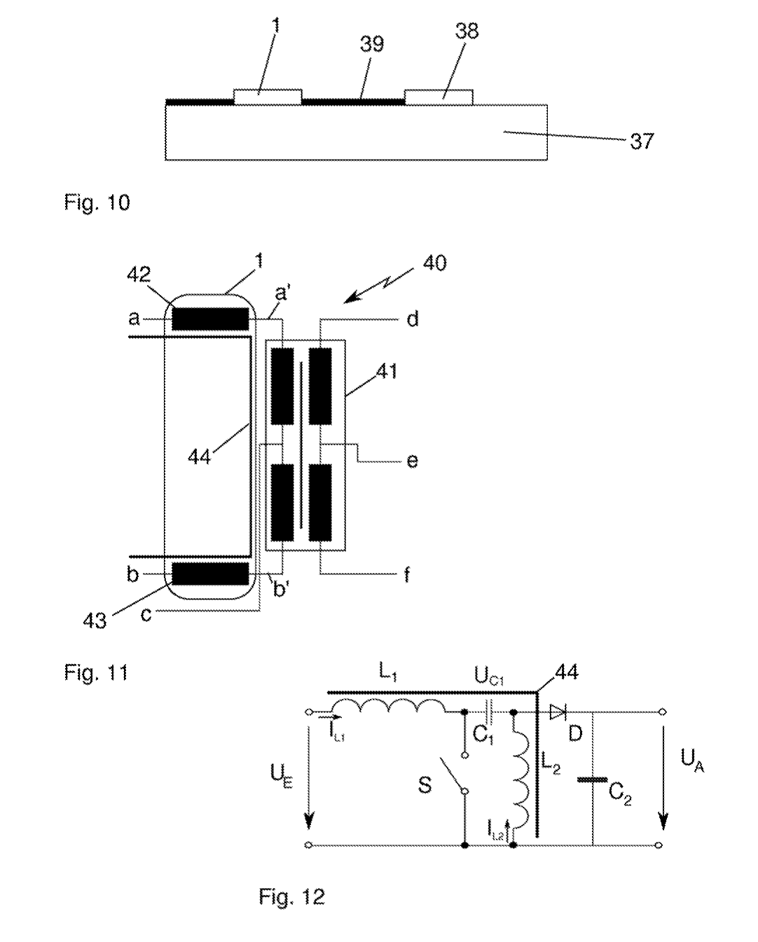

FIG. 10 shows a printed circuit board 37 with an electronic circuit 38 and an embodiment of an inventive electronic component 1. For example, the component 1 is in the form of a transformer and is connected with the electronic circuit through conductor tracks 39 of the printed circuit board 37, to supply the circuit 38 with an operating voltage when a voltage source (not shown) is connected to the component 1.

For example, the circuit 38 is a drive circuit for an automobile headlight.

Embodiments of an inventive electronic component can be used as an interference suppression choke, in particular a current-compensated choke or a common mode choke (CMC). Such current-compensated chokes are known in the prior art and are used to suppress emitted interference. For common-mode interference, a current-compensated choke forms a very high inductance, since the interfering currents are not compensated in it. To accomplish this, current-compensated chokes are used at the inputs and outputs of switched mode power supplies and in network filters, especially also in LAN transformers.

FIG. 11 shows an embodiment of a LAN transformer 40 that comprises a transformer 41 and an embodiment of the component 1, which here is in the form of, and is connected as, a common mode choke (CMC).

Here component 1 has 4 terminals and, according to the embodiment according to FIGS. 2-9 two planar coils, which belong to the magnetic circuit 44 formed by the magnetic conductor elements 5 and 6. The first planar coil 42 (cf. primary coil 15) has the connections a (corresponding to connection contact 21) and a′ (corresponding to connection contact 22), and the second planar coil 43 has connection contact b (corresponding to connection contact 27) and connection contact b′ (corresponding to connection contact 28).

The transformer 41 has the signal inputs d and f and the ground conductor e. On the output side, the transformer 41 has the ground conductor c and is connected with the connection contacts a′ and b′ of component 1, in order, for example, to couple in an input signal applied to the signal inputs d and f through the transformer 41 and the common mode choke formed by the component 1 into a LAN cable, which is located on the side of the common mode choke 1.

According to embodiments of the invention, an inventive component 1 is used to realize a DC-DC converter, in particular a capacitor-coupled switching regulator, in particular for a SEPIC converter (abbreviation for single ended primary inductance converter), a CUK converter, or a zeta converter.

FIG. 12 shows the circuit diagram of a SEPIC converter, as it is known in principle from the prior art (https://de.wikipedia.org/wiki/sepic). In contrast to the prior art, according to the invention the inductances L1 and L2 are realized by an embodiment of the inventive component 1, the inductances L1 and L2 belonging to the magnetic circuit 44, which is formed by the conductor elements 5 and 6. The coupling coefficient of the inductances L1 and L2 can be, for example, 0.5 to 0.9, especially 0.6 to 0.8. The electronic components of the SEPIC converter can be arranged according to the embodiment according to FIG. 9; cf. the electronic components 36 shown there.

The SEPIC converter according to FIG. 12 can be used as a DC/DC converter to operate LEDs as driving light in the automobile. The input voltage UE can be the motor vehicle electrical system voltage of about 12 V and the output voltage UA can be the operating voltage of about 6.6 V required for operation of an LED module, for example.

### LIST OF REFERENCE NUMBERS

1 Component
2 Printed circuit board layer
3 Printed circuit board layer
4 Cavity
5 First magnetic conductor element
6 Second magnetic conductor element
7 Coil package
8 First end
9′ Second end
9″ Second end
10 First end
11′ Second end
11″ Second end
12′ Bridge-shaped area
12″Bridge-shaped area
13′ Bridge-shaped area
13″Bridge-shaped area
14 Air gap
15 Primary coil
16 Secondary coil
17 Part
18 Printed circuit board layer
19 Part
20 Feedthrough
21 Connection contact
22 Connection contact
23 Part
24 Printed circuit board layer
25 Part
26 Feedthrough
27 Connection contact
28 Connection contact
29 Printed circuit board layer
30 Printed circuit board layer
31 Printed circuit board layer
32 Spring element
33 Spring element
34 Connection pad
35 Polyurethane foam
36 Electronic component
37 Printed circuit board
38 Electronic circuit
39 Conductor tracks
40 LAN transformer
41 Transformer
42 Planar coil
43 Planar coil
44 Magnetic circuit

What is claimed is:

1. An electronic component comprising:
a cavity;
a magnetic circuit arranged within the cavity, the magnetic circuit being formed by first and second magnetic conductor elements including a plurality of planar coils located between the first and second magnetic conductor elements, each of the first and second magnetic conductor elements including:
bridge-shaped areas; and
turns of the plurality of planar coil passing through between the bridge-shaped areas of the first and second magnetic conductor elements, each of the bridge-shaped area including first ends and second ends, the first ends that are opposite one another forming a coil core for one of the plurality of planar coils the second ends that are opposite one another closing the magnetic circuit on a periphery of the one of the plurality of planar coils.

2. The electronic component according to claim 1, wherein each of the first and second magnetic conductor elements is bow-shaped, star-shaped, or x-shaped and includes multiple bridge-shaped areas, which are arranged around the first ends at same or different angular distances.

3. The electronic component according to claim 1, wherein at least one of the plurality of planar coils is formed on a printed circuit board layer.

4. The electronic component according to claim 3, wherein a first planar coil of the plurality of planar coils forms a primary side of a transformer and a second planar coil of the plurality of planar coils forms a secondary side of the transformer, the first and second planar coils being arranged to be mirror symmetric to one another.

5. The electronic component according to claim 4, wherein a first part of at least one of the plurality of planar coils is arranged on a first side of the printed circuit board layer and a second part of the at least one of the plurality of planar coils is arranged on a second side of the printed circuit board layer opposite the first side, the first and second parts of the planar coil being electrically connected with one another by a via passing through the printed circuit board layer.

6. The electronic component according to claim 5, wherein:
the printed circuit board layer includes a plurality of printed circuit board layers including a first printed circuit board layer and a second printed circuit board layer; and
the first and second planar coils are formed on first and second printed circuit board layers, insulation layers being arranged between the first and second printed circuit board layers and on at least one surface of each of the first and second printed circuit board layers, the first and second printed circuit board layers and the insulation layers forming a coil package as a structural unit.

7. The electronic component according to claim 6, the coil package being arranged between the first and second magnetic conductor elements, the cavity being designed so that the magnetic circuit is fixed in the cavity, so that at least the second ends of the opposite conductor elements touch one another, the bridge-shaped areas of the conductor elements each extending parallel to the first and second planar coils.

8. The electronic component according to claim 7, wherein an air gap is formed between the first ends.

9. The electronic component according to claim 1, wherein the cavity is formed by one or more printed circuit board layers.

10. The electronic component according to claim 9, wherein the one or more printed circuit board layers have a coefficient of thermal expansion that is greater than that of ferrite of which the first and second magnetic conductor elements are formed; and
the magnetic circuit further including at least one elastic element arranged in the cavity, the at least one elastic element configured to press the first and second magnetic conductor elements against one another to compensate for different coefficients of thermal expansion.

11. The electronic component according to claim 10, wherein the at least one elastic element is formed by a spring element.

12. The electronic component according to claim 11, wherein spring travel of the spring element is 10 μm to 30 μm.

13. The electronic component according to claim 11, wherein the electronic component is in the form of a multilayer component, and a printed circuit board layer of the multilayer component comprises the spring element.

14. The electronic component according to claim 10, wherein the at least one elastic element is formed by foam arranged in the cavity.

15. The electronic component according to claim 1, wherein an end face of the first end is equal to sum of end faces of the second ends of one of the first and second conductor elements, the first and second conductor elements preferably having an identical shape.

16. A printed circuit board comprising:
at least one printed circuit board layer; and
an electronic component arranged on or in the at least one printed circuit board layer, the electronic component including:
a cavity;
a magnetic circuit arranged within the cavity, the magnetic circuit formed by first and second magnetic conductor elements including a plurality of planar coils located between the first and second magnetic conductor elements, each of the first and second magnetic conductor elements including:
bridge-shaped areas; and
turns of the plurality of planar coils passing through between the bridge-shaped areas of the first and second magnetic conductor elements, each of the bridge-shaped areas including first ends and second ends, the first ends that are opposite one another forming a coil core for one of the plurality of planar coils, the second ends that are opposite one another closing the magnetic circuit on a periphery of the one of the plurality of planar coils.

17. The printed circuit board according to claim 16, including an electronic circuit that has an operating voltage, the electronic component being electrically connected to the electronic circuit and configured to make the operating voltage available.

18. The printed circuit board according to claim 16, further including a circuit with an interference suppression choke and the electronic component, the interference suppression choke including at least one of a current-compensated choke or a common mode choke.

19. The printed circuit board of claim 18, wherein the circuit includes a switched mode power supply or network filter.

20. The printed circuit board of claim 16, further including a DC-DC converter with the electronic component.

21. A production process for an electronic component, the production process comprising:
producing at least one planar coil on a substrate;
applying insulation layers onto the substrate to form a coil package;
forming a magnetic circuit with the coil package arranged between first and second magnetic conductor elements formed within a cavity that is formed in at least one printed circuit board structure.

22. The production process according to claim 21, wherein the cavity is formed by at least one of a forming tool, a stamping tool, and an embossing roller.

23. The production process according to claim 21, wherein the printed circuit board structure and the magnetic circuit form a stack structure, which is formed by applying pressure to a structural unit in a multilayer process.
